(19) United States
(12) Patent Application Publication
(10) Pub. No.: US 2025/0341424 A1
(43) Pub. Date: Nov. 6, 2025

(54) INFRARED DETECTOR

(71) Applicant: HAMAMATSU PHOTONICS K.K., Hamamatsu-shi, Shizuoka (JP)

(72) Inventors: Katsumi SHIBAYAMA, Hamamatsu-shi, Shizuoka (JP); Takafumi YOKINO, Hamamatsu-shi, Shizuoka (JP); Masaaki MUTO, Hamamatsu-shi, Shizuoka (JP); Katsuhiko KATO, Hamamatsu-shi, Shizuoka (JP)

(73) Assignee: HAMAMATSU PHOTONICS K.K., Hamamatsu-shi, Shizuoka (JP)

(21) Appl. No.: 18/867,099

(22) PCT Filed: Apr. 3, 2023
(86) PCT No.: PCT/JP2023/013848

§ 371 Date: Nov. 19, 2024

(30) Foreign Application Priority Data
Jun. 24, 2022 (JP) 2022-101653

(51) Int. Cl. G01J 5/14; G01J 5/12; H10N 19/00

(52) U.S. Cl. CPC G01J 5/14; H10N 19/00; G01J 2005/123

(57) ABSTRACT

An infrared detector includes a package having a base portion, first to third lead pins, and a cap portion, and a plurality of thermopile chips. First and second thermopile chips are electrically connected in series, and a first chip unit and a second chip unit are electrically connected in parallel. The first and second lead pins are arranged side by side in a second direction via a first straight line, the first and third lead pins are arranged side by side in the first direction via a second straight line, the first thermopile chip is disposed on the second straight line and disposed on a straight line connecting the first and third lead pins, and the second and third thermopile chips are arranged side by side on the first straight line via a reference position.

### TECHNICAL FIELD

The present disclosure relates to an infrared detector.

### BACKGROUND ART

As a technique related to the infrared detector, for example, Patent Literature 1 describes an infrared detection element including a package having a base portion and a plurality of thermopile chips arranged on a main surface of the base portion. In the infrared detection element described in Patent Literature 1, the plurality of thermopile chips are electrically connected in series.

### CITATION LIST

### Patent Literature

Patent Literature 1: Japanese Unexamined Patent Publication No. 2000-19019

### SUMMARY OF INVENTION

### Technical Problem

In recent years, for example, while application of the infrared detector to various fields and applications progresses, an infrared detector with high sensitivity may be desired. In this regard, in the above-described technique, a resistance value of a circuit constituting the infrared detector may increase due to the presence of the plurality of thermopile chips, and it is difficult to improve sensitivity. In addition, in the above-described technique, there is a restriction on arrangement of the thermopile chips on the main surface, and it is not easy to ensure a large light receiving area, and thus it is difficult to improve the sensitivity.

Therefore, an object of the present disclosure is to provide an infrared detector capable of improving the sensitivity.

### Solution to Problem

(1) An infrared detector according to one aspect of the present disclosure includes: a package including a base portion, first to third lead pins protruding from a main surface of the base portion, and a cap portion disposed on the main surface of the base portion and defining a housing space together with the base portion; and a plurality of thermopile chips arranged on the main surface of the base portion, in which the plurality of thermopile chips include first to third thermopile chips, the first and second thermopile chips are electrically connected in series, a first chip unit including the first and second thermopile chips and a second chip unit including the third thermopile chip are electrically connected in parallel, in a case where as viewed from a direction perpendicular to the main surface of the base portion, a straight line passing through a reference position and extending in a first direction is a first straight line, and a straight line passing through the reference position and extending in a second direction orthogonal to the first direction is a second straight line, the first and second lead pins are arranged side by side in the second direction via the first straight line, the first and third lead pins are arranged side by side in the first direction via the second straight line, the first thermopile chip is disposed on the second straight line and disposed on a straight line connecting the first and third lead pins, and the second and third thermopile chips are arranged side by side on the first straight line via the reference position.

In the infrared detector according to one aspect of the present disclosure, the first chip unit including the first and second thermopile chips electrically connected in series and the second chip unit including the third thermopile chip are electrically connected in parallel, so that the resistance value of the circuit can be reduced as compared with a case where the first to third thermopile chips are electrically connected in series. In addition, the arrangement of the first to third thermopile chips can be optimized to ensure a large light receiving area while there is a restriction on the arrangement of the thermopile chips on the main surface due to a package structure in which the plurality of lead pins protrude from the main surface. Therefore, according to the infrared detector according to one aspect of the present disclosure, the sensitivity can be improved.

(2) In the infrared detector according to the above (1), a light passing opening facing the main surface of the base portion may be formed in the cap portion, and the light passing opening may overlap the first to third thermopile chips and may not overlap the first to third lead pins as viewed from the direction perpendicular to the main surface of the base portion. Thus, the infrared rays can be efficiently incident on the light receiving surfaces of the first to third thermopile chips while preventing the infrared rays passing through the light passing opening from hitting the first to third lead pins and being irregularly reflected to generate noise.

(3) In the infrared detector according to the above (1) or (2), the plurality of thermopile chips may further include a fourth thermopile chip disposed on the main surface of the base portion and included in the second chip unit, the third and fourth thermopile chips may be electrically connected in series, and the first and fourth thermopile chips may be arranged side by side on the second straight line via the reference position as viewed from the direction perpendicular to the main surface of the base portion. This makes it possible to optimize the arrangement of the first to fourth thermopile chips to ensure a large light receiving area, while suppressing the resistance value of the circuit to the same resistance value as in a case of using one thermopile chip.

(4) In the infrared detector according to any one of the above (1) to (3), a light passing opening facing the main surface of the base portion may be formed in the cap portion, and the light passing opening may overlap the first to fourth thermopile chips and may not overlap the first to third lead pins as viewed from the direction perpendicular to the main surface of the base portion. Thus, the infrared rays can be efficiently incident on the light receiving surfaces of the first to fourth thermopile chips while preventing the infrared rays passing through the light passing opening from being irregularly reflected by the first to third lead pins to generate noise.

(5) In the infrared detector according to any one of the above (1) to (4), the first thermopile chip may be electrically connected to the third lead pin by a first wire, the second thermopile chip may be electrically connected to the second lead pin by a second wire, the third thermopile chip may be electrically connected to the third lead pin by a third wire, the fourth thermopile chip may be electrically connected to the second lead pin by a fourth wire, the first and second thermopile chips may be electrically connected to each other by a fifth wire, and the third and fourth thermopile chips may be electrically connected to each other by a sixth wire. In this case, as the arrangement of the first to fourth thermopile chips can be optimized, a length of each wire can be shortened to reduce the resistance value, and the sensitivity can be further improved.

(6) In the infrared detector according to any one of the above (1) to (5), the thermopile chip and the light passing opening may both have a rectangular shape as viewed from the direction perpendicular to the main surface of the base portion, and a straight line along a diagonal line of the thermopile chip may be inclined by 45° with respect to a straight line along a diagonal line of the light passing opening. Thus, the infrared rays can be efficiently incident on the light receiving surfaces of the plurality of thermopile chips while preventing the infrared rays from hitting the first to third lead pins through the light passing opening.

(7) In the infrared detector according to any one of the above (1) to (6), the thermopile chip and the light passing opening may both have a square shape as viewed from the direction perpendicular to the main surface of the base portion, and a length of one side of the light passing opening may be larger than twice a length of one side of the thermopile chip. By increasing the light passing opening in this manner, the infrared rays can be efficiently incident on the light receiving surface of the thermopile chip.

(8) In the infrared detector according to any one of the above (1) to (7), each of the thermopile chips may include a membrane formed in a central portion as viewed from the direction perpendicular to the main surface of the base portion, and an edge portion surrounding the membrane, and the light passing opening may overlap the membrane of the thermopile chip and may not overlap at least a part of the edge portion as viewed from the direction perpendicular to the main surface of the base portion. This makes it possible to easily realize a configuration in which the light passing opening does not overlap the first to third lead pins as viewed from the direction perpendicular to the main surface of the base portion, while the infrared rays are efficiently incident on a membrane on which a hot junction is formed.

(9) In the infrared detector according to any one of the above (1) to (8), the light passing opening may be disposed on a straight line connecting the first and second lead pins and disposed on a straight line connecting the first and third lead pins as viewed from the direction perpendicular to the main surface of the base portion. Thus, the light passing opening is disposed on the plurality of thermopile chips, and the infrared rays can be efficiently incident on the light receiving surfaces of the plurality of thermopile chips through the light passing opening.

(10) In the infrared detector according to any one of the above (1) to (9), at least a part of the second thermopile chip may be located between the first thermopile chip and the fourth thermopile chip, and at least a part of the third thermopile chip may be located between the first thermopile chip and the fourth thermopile chip as viewed from the direction perpendicular to the main surface of the base portion. Thus, the second thermopile chip and the third thermopile chip can be brought close to each other in the first direction, and the infrared rays can be efficiently incident on the light receiving surfaces of the second and third thermopile chips.

(11) In the infrared detector according to any one of the above (1) to (10), the package may further include a fourth lead pin protruding from the main surface of the base portion, when viewed from the direction perpendicular to the main surface of the base portion, the second and fourth lead pins may be arranged side by side in the first direction via the second straight line, and the fourth thermopile chip may be disposed on a straight line connecting the second and fourth lead pins. Thus, the infrared rays can be efficiently incident on the light receiving surface of the fourth thermopile chip.

(12) In the infrared detector according to any one of the above (1) to (11), a light passing opening facing the main surface of the base portion may be formed in the cap portion, and the light passing opening may overlap the first to fourth thermopile chips and may not overlap the first to fourth lead pins as viewed from the direction perpendicular to the main surface of the base portion. Thus, the infrared rays can be efficiently incident on the light receiving surfaces of the first to fourth thermopile chips while preventing the infrared rays from hitting the first to fourth lead pins through the light passing opening.

(13) In the infrared detector according to any one of the above (1) to (12), the plurality of thermopile chips may further include a fifth thermopile chip disposed on the main surface of the base portion and included in the first chip unit, and the first, second, and fifth thermopile chips may be electrically connected in series. This makes it possible to further improve the sensitivity due to the presence of the fifth thermopile chip.

(14) In the infrared detector according to any one of the above (1) to (13), the plurality of thermopile chips may further include a fifth thermopile chip disposed on the main surface of the base portion and included in the first chip unit, the first, second, and fifth thermopile chips may be electrically connected in series, and the fifth thermopile chip may be disposed so as to overlap the reference position between the second and third thermopile chips as viewed from the direction perpendicular to the main surface of the base portion. This makes it possible to further improve the sensitivity due to the presence of the fifth thermopile chip, and to optimize the arrangement of the first to fifth thermopile chips to ensure a large light receiving area.

(15) In the infrared detector according to any one of the above (1) to (14), a light passing opening facing the main surface of the base portion may be formed in the cap portion, and the light passing opening may overlap the first to fifth thermopile chips and may not overlap the first to third lead pins as viewed from the direction perpendicular to the main surface of the base portion. Thus, the infrared rays can be efficiently incident on the light receiving surfaces of the first to fifth thermopile chips while preventing the infrared rays from hitting the first to third lead pins through the light passing opening.

(16) In the infrared detector according to any one of the above (1) to (15), the reference position may overlap a center position of the light passing opening as viewed from the direction perpendicular to the main surface of the base portion. Thus, the plurality of thermopile chips can be arranged based on the center position of the light passing opening as viewed from the direction perpendicular to the main surface of the base portion, and the infrared rays passing through the light passing opening can be efficiently incident on the light receiving surfaces of the plurality of thermopile chips.

### Advantageous Effects of Invention

According to the present disclosure, it is possible to provide an infrared detector capable of improving sensitivity.

### BRIEF DESCRIPTION OF DRAWINGS

FIG. 1 is a plan view illustrating an infrared detector according to a first embodiment.

FIG. 2 is a sectional view taken along line II-II of FIG. 1.

FIG. 3 is a sectional view taken along line III-III of FIG. 1.

FIG. 4 is a sectional perspective view illustrating a thermopile chip of FIG. 1.

FIG. 5 is a view schematically illustrating a section of the thermopile chip of FIG. 4.

FIG. 6 is a plan view illustrating the infrared detector of FIG. 1 with a window portion omitted.

FIG. 7 is a perspective view illustrating a part of the infrared detector of FIG. 1.

FIG. 8 is a plan view illustrating a schematic structure of the infrared detector of FIG. 1.

FIG. 9 is a schematic circuit diagram illustrating electrical connection of the thermopile chip in the infrared detector of FIG. 1.

FIG. 10 is a perspective view illustrating a part of the infrared detector according to a second embodiment.

FIG. 11 is a plan view illustrating the schematic structure of the infrared detector of FIG. 10.

FIG. 12 is a schematic circuit diagram illustrating the electrical connection of the thermopile chip in the infrared detector of FIG. 10.

FIG. 13 is a perspective view illustrating a part of the infrared detector according to a third embodiment.

FIG. 14 is a plan view illustrating the schematic structure of the infrared detector of FIG. 13.

FIG. 15 is a schematic circuit diagram illustrating the electrical connection of the thermopile chip in the infrared detector of FIG. 13.

FIG. 16 is a perspective view illustrating a part of the infrared detector according to a first modification.

FIG. 17 is a plan view illustrating the schematic structure of the infrared detector of FIG. 16.

FIG. 18 is a perspective view illustrating a part of the infrared detector according to a second modification.

FIG. 19 is a plan view illustrating the schematic structure of the infrared detector of FIG. 18.

### DESCRIPTION OF EMBODIMENTS

Hereinafter, embodiments will be described in detail with reference to the drawings. In the drawings, the same or corresponding parts are denoted by the same reference signs, and redundant description will be omitted. For convenience of description, three directions orthogonal to each other will be respectively described as an “X direction”, a “Y direction”, and a “Z direction”.

### First Embodiment

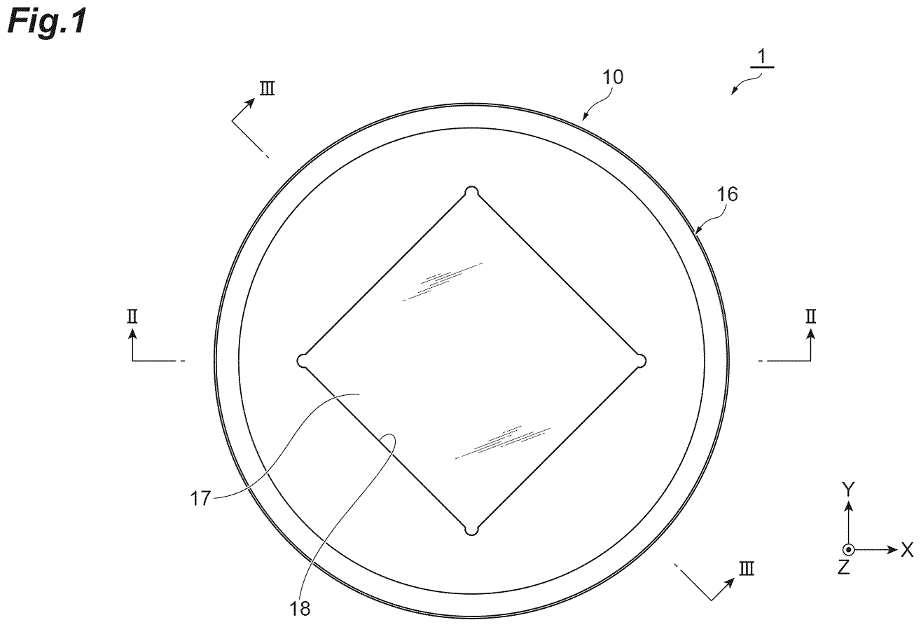

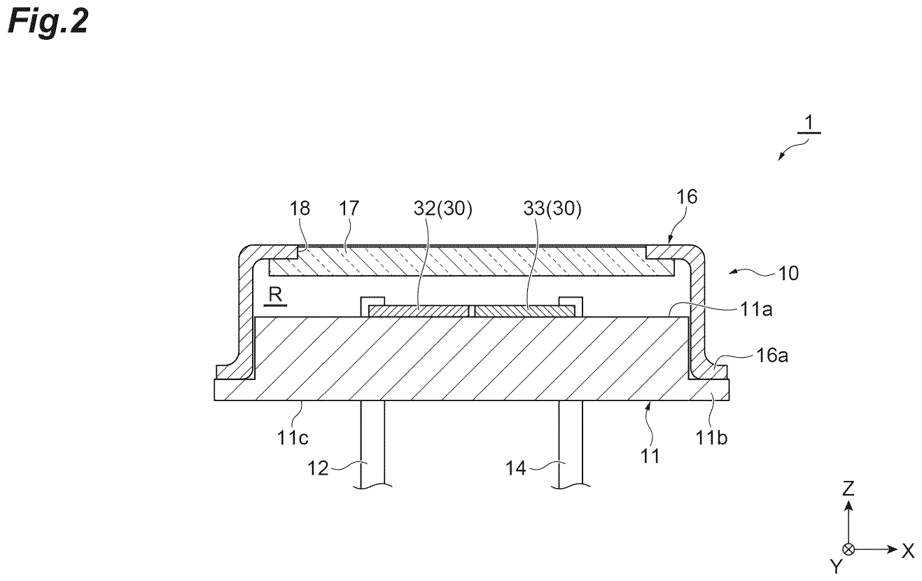

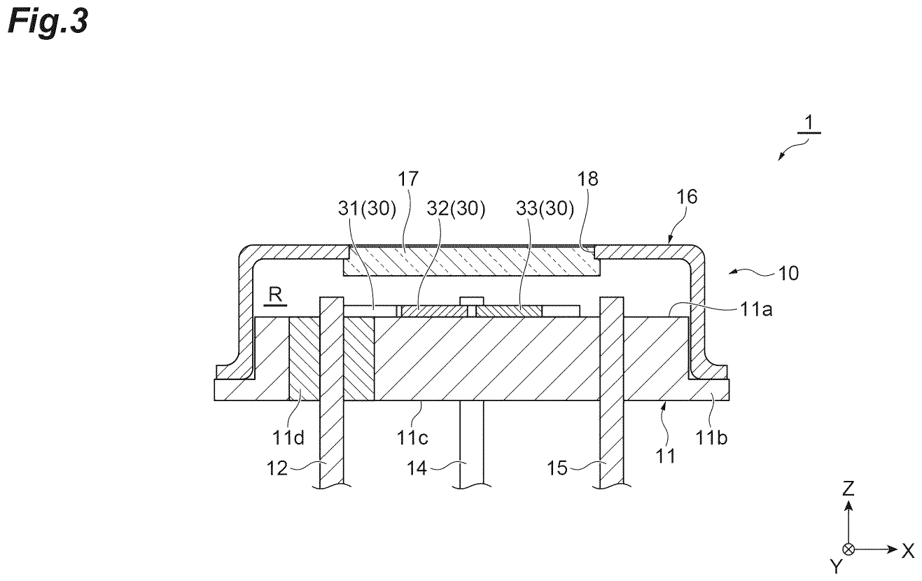

As illustrated in FIGS. 1, 2, and 3, an infrared detector 1 according to a first embodiment is a detector that detects infrared rays. The infrared detector 1 is used for, for example, radiation thermometer, gas analysis, flame detection, or the like. Here, the infrared detector 1 is a high-sensitivity type detector for flame detection, and detects the infrared rays due to CO₂ resonance radiation from flame. The infrared detector 1 includes a package 10 having a housing space R, and a plurality of thermopile chips 30 arranged in the housing space R.

The package 10 includes a base portion 11, a first lead pin 12, a second lead pin 13, a third lead pin 14, a fourth lead pin 15, a cap portion 16, and a window portion 17. The base portion 11 has a disk shape with the Z direction as a thickness direction. The plurality of thermopile chips 30 are mounted on a main surface 11a of the base portion 11 on one side in the Z direction. The main surface 11a is a circular flat surface as viewed from the Z direction. A flange portion 11b protruding radially outward is provided at an end portion of the base portion 11 on the other side in the Z direction. The base portion 11 is formed of, for example, a material containing Kovar. A diameter of the base portion 11 is, for example, about 10 mm. A thickness of the base portion 11 is, for example, about 2 mm.

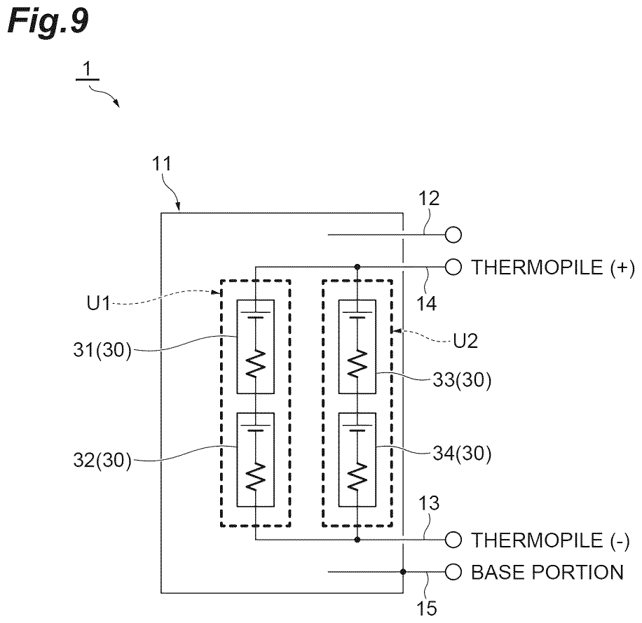

The first to fourth lead pins 12 to 15 are terminal members protruding from the main surface 11a in the base portion 11. The first to fourth lead pins 12 to 15 extend in the Z direction so as to penetrate the base portion 11. The first to fourth lead pins 12 to 15 also protrude from a main surface 11c of the base portion 11 on the other side in the Z direction. The first to fourth lead pins 12 to 15 are arranged apart from each other. Insulating portions 11d such as hermetic glass are provided around the first to third lead pins 12 to 14 in the base portion 11. Accordingly, the first to third lead pins 12 to 14 are insulated from the base portion 11. The insulating portion 11d is not provided around the fourth lead pin 15 in the base portion 11. Thus, the fourth lead pin 15 is electrically connected to the base portion 11 and functions as a ground (see FIG. 9). Heights from the main surface 11a of the base portion 11 to upper surfaces of the first to fourth lead pins 12 to 15 (protrusion amounts of the first to fourth lead pins 12 to 15) are larger than heights from the main surface 11a of the base portion 11 to upper surfaces of the thermopile chips 30 (thicknesses of the thermopile chips 30).

The cap portion 16 is disposed on the main surface 11a of the base portion 11, and defines the housing space R with the base portion 11. The cap portion 16 has a circular cup shape opened to the other side in the Z direction. An inner diameter of the cap portion 16 corresponds to an outer diameter of the base portion 11. A flange portion 16a protruding radially outward is provided at an end portion on an opening side of the cap portion 16. The cap portion 16 is disposed coaxially with the base portion 11 so as to cover the main surface 11a of the base portion 11. The cap portion 16 is fixed to the base portion 11 in a state where the flange portion 16a is in contact with the flange portion 11b of the base portion 11. A center position of the cap portion 16 coincides with a center position of the main surface 11a of the base portion 11 as viewed from the Z direction. The housing space R is defined by a bottom surface and an inner peripheral surface of the cap portion 16 and the main surface 11a of the base portion 11.

The cap portion 16 is formed with a light passing opening 18 facing the main surface 11a of the base portion 11. The light passing opening 18 is a through-hole penetrating the cap portion 16 in the Z direction, and communicates an inside and an outside of the cap portion 16 (housing space R). The light passing opening 18 has a rectangular shape, specifically, a square shape as viewed from the Z direction.

A distance from the upper surface of the thermopile chip 30 to an inner surface of the cap portion 16 facing the thermopile chip 30 is, for example, about 1 mm. The distance from the upper surface of the thermopile chip 30 to the inner surface of the cap portion 16 facing the thermopile chip 30 is smaller than the thickness of the base portion. By reducing the distance from the upper surface of the thermopile chip 30 to the inner surface of the cap portion 16 facing the thermopile chip 30, a viewing angle of the thermopile chip 30 can be increased, and the infrared rays can be efficiently incident on the light receiving surface. A distance from the main surface 11c on the other side in the Z direction of the base portion 11 to an outer surface of the cap portion 16 (an outer surface of a portion to which the window portion 17 is attached) is, for example, about 3 mm.

The window portion 17 is provided in the cap portion 16 so as to close the light passing opening 18. Here, the window portion 17 is fixed to an inner side of the cap portion 16 at a side edge of the light passing opening 18 of the cap portion 16 so as to close the light passing opening 18. The window portion 17 has a plate shape with the Z direction as the thickness direction. The window portion 17 is fitted into the light passing opening 18 from the inner side of the cap portion 16. The window portion 17 is formed of a material (for example, silicon) having infrared transparency. The window portion 17 constitutes, for example, a bandpass filter that cuts off light having a wavelength other than that of the infrared rays. The infrared rays enter the housing space R through the window portion 17. The window portion 17 is formed with a portion having a reduced thickness at its outer edge in order to be fitted into the cap portion 16. Thus, a fixing strength between the cap portion 16 and the window portion 17 can be increased. A thickness of the window portion 17 is, for example, 0.5 mm. The thickness of the window portion 17 is larger than that of the thermopile chip 30.

The thermopile chip 30 is a thermal type detection sensor that uses the Seebeck effect to obtain a thermoelectromotive force proportional to an amount of infrared incident energy. The thermopile chip 30 can detect an absolute amount of the infrared rays. The plurality of thermopile chips 30 are arranged on the main surface 11a of the base portion 11. The thermopile chip 30 is a rectangular chip as viewed from the Z direction. The thermopile chip 30 has a square shape as viewed from the Z direction. The surface of the thermopile chip 30 constitutes the light receiving surface. The thermopile chip 30 is a single-element thermopile. The light receiving surface of the thermopile chip 30 has a central portion having higher sensitivity than an edge portion as viewed from the Z direction.

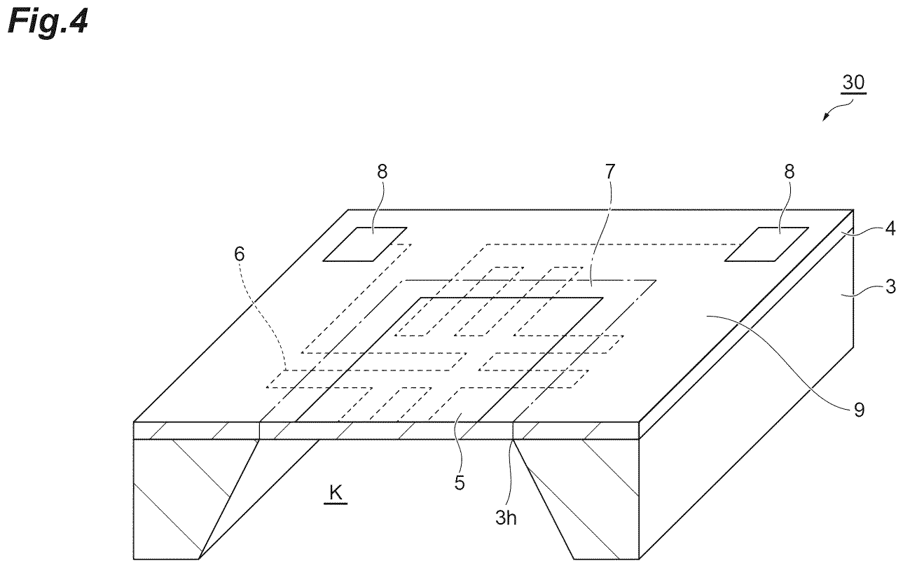

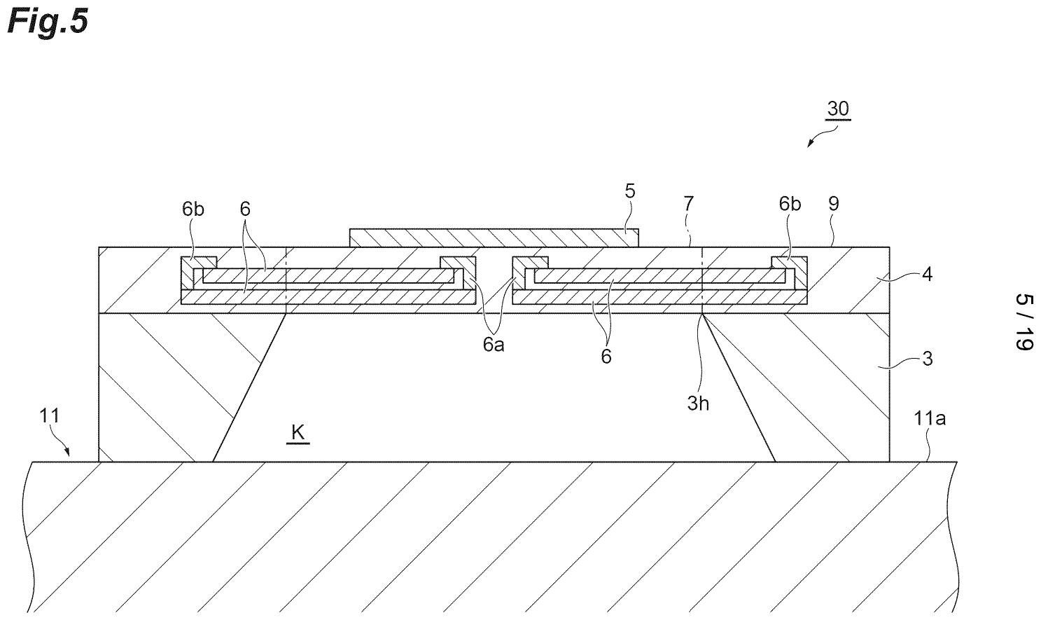

As illustrated in FIGS. 4 and 5, the thermopile chip 30 includes a substrate 3, an insulating film 4, an infrared absorbing film 5, and a plurality of thermocouples 6 electrically connected in series. The substrate 3 includes, for example, silicon. The substrate 3 has a rectangular shape as viewed from the Z direction, and has a rectangular opening 3h formed in a central portion. The insulating film 4 is provided on the substrate 3 so as to close the opening 3h formed in the substrate 3. A portion of the insulating film 4 that closes the opening 3h of the substrate 3 constitutes a membrane 7. The membrane 7 has a rectangular shape and is suspended in midair. Thus, since a space K is formed between the membrane 7 and the main surface 11a of the base portion 11, thermal separation between the membrane 7 and the base portion 11 is achieved. The insulating film 4 includes, for example, SiO₂ or SiN. The plurality of thermocouples 6 are each formed inside the insulating film 4 such that a hot junction 6a is located in the membrane 7 and a cold junction 6b is located in an edge portion 9 surrounding the membrane 7.

The infrared absorbing film 5 is provided on the membrane 7 of a surface of the insulating film 4. The infrared absorbing film 5 is a film for increasing infrared absorption efficiency. The infrared absorbing film 5 includes, for example, TiN or the like. An electrode pad (output terminal) 8 is formed on the edge portion 9 surrounding the membrane 7 of the surface of the insulating film 4. The electrode pad 8 is a terminal for extracting the thermoelectromotive force as a signal to an outside, and is electrically connected to the plurality of thermocouples 6. The electrode pad 8 is formed at each of four corners on the surface of the insulating film 4. Two of the four electrode pads 8 are electrically connected to the outside via wires. When the infrared rays are incident on the membrane 7, the hot junction 6a located in the membrane 7 is warmed, and a temperature difference is generated between the hot junction 6a and the cold junction 6b located in the edge portion 9 surrounding the membrane 7. By extracting the thermoelectromotive force associated with the temperature difference from the electrode pad 8 to the outside as a signal, the infrared rays can be detected. A size of the thermopile chip 30 is, for example, about 1 to 2 mm on one side. A thickness of the thermopile chip 30 is, for example, about 200 μm. A thickness of the substrate 3 is, for example, 200 μm, and a thickness of the insulating film 4 is, for example, several μm (in FIG. 5, the thickness of the insulating film 4 is illustrated to be thick for the sake of explanation). The thickness of the insulating film 4 is smaller than the thickness of the substrate 3. A size of the membrane 7 is, for example, about 1 to 1.5 mm on one side.

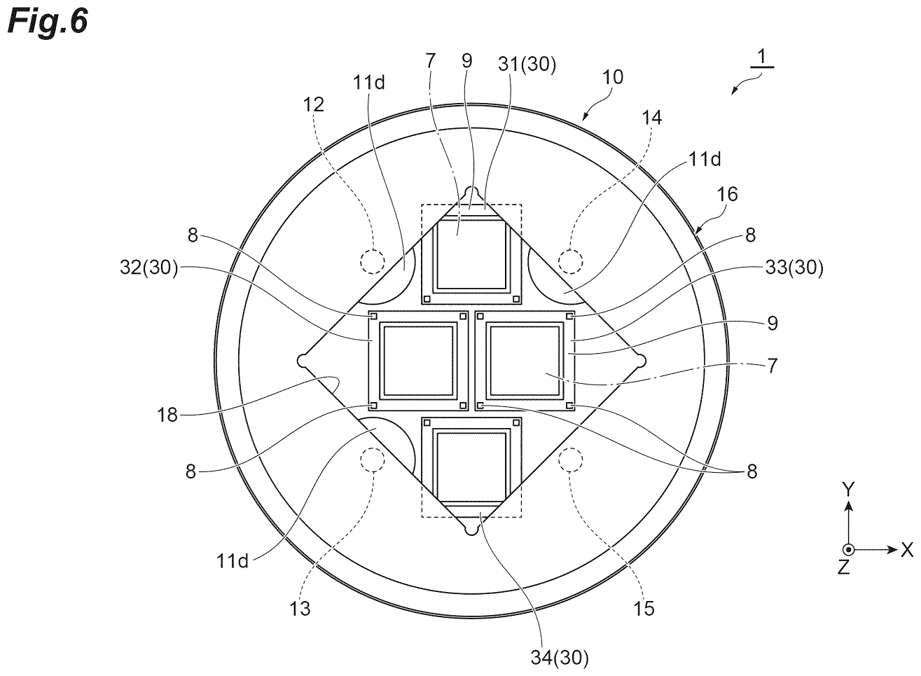

As illustrated in FIG. 6, as viewed from the Z direction, a straight line along a diagonal line of the thermopile chip 30 is inclined by 45° with respect to a straight line along a diagonal line of the light passing opening 18. As viewed from the Z direction, a length of one side of the light passing opening 18 is larger than twice a length of one side of the thermopile chip 30. The plurality of thermopile chips 30 includes a first thermopile chip 31, a second thermopile chip 32, a third thermopile chip 33, and a fourth thermopile chip 34. The first and second thermopile chips 31 and 32 are included in a first chip unit U1. The third and fourth thermopile chips 33 and 34 are included in a second chip unit U2.

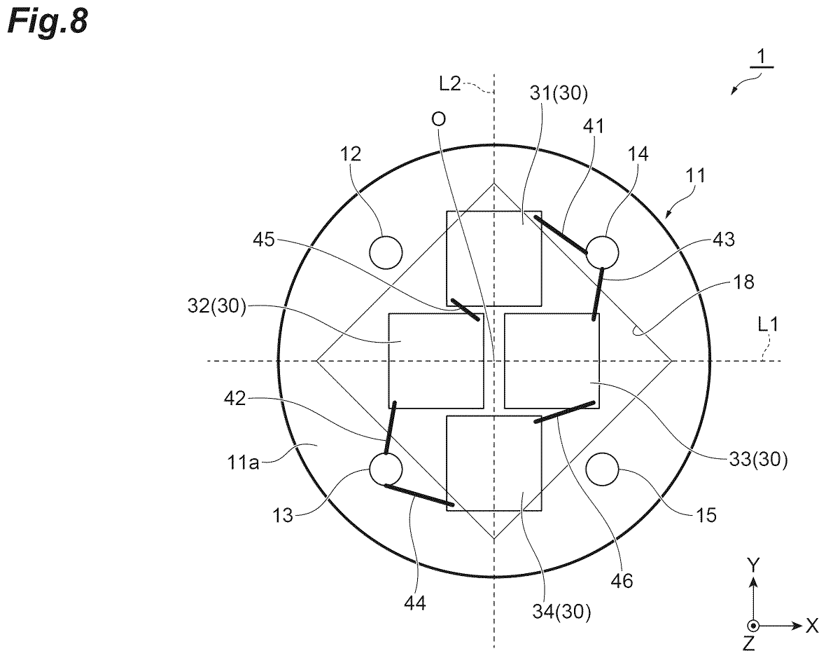

As illustrated in FIG. 8, the infrared detector 1 of the present embodiment has the following characteristics when a straight line passing through a reference position O and extending in the X direction (a first direction) is a first straight line L1, and a straight line passing through the reference position O and extending in the Y direction (a second direction) is a second straight line L2 as viewed from the Z direction. The reference position O is a center position (centroid position) of the main surface 11a of the base portion 11.

The first and second lead pins 12 and 13 are arranged side by side in the Y direction via the first straight line L1 on the main surface 11a. The first and third lead pins 12 and 14 are arranged side by side in the X direction via the second straight line L2 on the main surface 11a. The second and fourth lead pins 13 and 15 are arranged side by side in the X direction via the second straight line L2 on the main surface 11a.

In other words, the first to fourth lead pins 12 to 15 are positioned at corners of a square formed on the main surface 11a and having sides in the X direction and the Y direction as viewed from the Z direction. The first to fourth lead pins 12 to 15 are respectively located in regions divided into four by the first and second straight lines L1 and L2 on the main surface 11a. A distance to the first straight line L1 of each of the first to fourth lead pins 12 to 15 is equal to a distance to the second straight line L2 of each of the first to fourth lead pins 12 to 15. The first to fourth lead pins 12 to 15 are respectively arranged at positions rotationally symmetric about the reference position O by 90° as viewed from the Z direction. The distance to the first straight line L1 of each of the first to fourth lead pins 12 to 15 and the distance to the second straight line L2 of each of the first to fourth lead pins 12 to 15 are, for example, about 1 to 2 mm. A distance from the first lead pin 12 to the fourth lead pin 15 and a distance from the second lead pin 13 to the third lead pin 14 are, for example, about 5 mm.

The first and fourth thermopile chips 31 and 34 are arranged side by side on the second straight line L2 via the reference position O as viewed from the Z direction. The second and third thermopile chips 32 and 33 are arranged side by side on the first straight line L1 via the reference position O. The first thermopile chip 31 is disposed on a straight line connecting the first and third lead pins 12 and 14. The fourth thermopile chip 34 is disposed on a straight line connecting the second and fourth lead pins 13 and 15.

A part of the second thermopile chip 32 is located between the first thermopile chip 31 and the fourth thermopile chip 34 as viewed from the Z direction. A part of the third thermopile chip 33 is located between the first thermopile chip 31 and the fourth thermopile chip 34. The second thermopile chip 32 and the third thermopile chip 33 are close to each other in the X direction. The first thermopile chip 31 and the second and third thermopile chips 32 and 33 are close to each other in the Y direction. The second and third thermopile chips 32 and 33 and the fourth thermopile chip 34 are close to each other in the Y direction. The thermopile chips 30 are arranged in a staggered manner on the main surface 11a. The thermopile chips 30 are arranged to form an elongated rhombus in the Y direction as a whole. A maximum of two thermopile chips 30 are arranged in the X direction, and a maximum of three thermopile chips 30 are arranged in the Y direction.

The light passing opening 18 overlaps the first to fourth thermopile chips 31 to 34 and does not overlap the first to fourth lead pins 12 to 15 as viewed from the Z direction. The light passing opening 18 includes at least a part of the first to fourth thermopile chips 31 to 34 and does not include the first to fourth lead pins 12 to 15 as viewed from the Z direction. In other words, the light passing opening 18 is present immediately above the first to fourth thermopile chips 31 to 34, while the light passing opening 18 is not present immediately above the first to fourth lead pins 12 to 15. The reference position O overlaps (coincides with) a center position of the light passing opening 18 as viewed from the Z direction.

The light passing opening 18 overlaps at least parts of the membranes 7 formed in central portions of the first to fourth thermopile chips 31 to 34 as viewed from the Z direction. The light passing opening 18 does not overlap at least a part of the edge portion 9 of the thermopile chip 30 surrounding the membrane 7 as viewed from the Z direction. The light passing opening 18 overlaps parts of the insulating portions 11d of the first to third lead pins 12 to 14 as viewed from the Z direction. The light passing opening 18 overlaps entire surfaces of the second and third thermopile chips 32 and 33, and overlaps parts of the first and fourth thermopile chips 31 and 34 as viewed from the Z direction. One corner of the light passing opening 18 is located on a side opposite to the reference position O via the first thermopile chip 31 on the second straight line L2, and a corner facing the corner is located on a side opposite to the reference position O via the fourth thermopile chip 34 on the second straight line L2. A size of the light passing opening 18 is, for example, about 4 to 5 mm on one side.

The light passing opening 18 is disposed on a straight line connecting any two of the first to fourth lead pins 12 to 15 as viewed from the Z direction. Specifically, as viewed from the Z direction, the light passing opening 18 is disposed on a straight line connecting the first and second lead pins 12 and 13, and is disposed on a straight line connecting the first and third lead pins 12 and 14. As viewed from the Z direction, the light passing opening 18 is disposed on the straight line connecting the second and fourth lead pins 13 and 15, and is disposed on a straight line connecting the third and fourth lead pins 14 and 15. As viewed from the Z direction, the light passing opening 18 is disposed on a straight line connecting the first and fourth lead pins 12 and 15, and is disposed on a straight line connecting the second and third lead pins 13 and 14.

As illustrated in FIGS. 8 and 9, the first and second thermopile chips 31 and 32 are electrically connected in series. The third and fourth thermopile chips 33 and 34 are electrically connected in series. The first chip unit U1 including the first and second thermopile chips 31 and 32 and the second chip unit U2 including the third and fourth thermopile chips 33 and 34 are electrically connected in parallel.

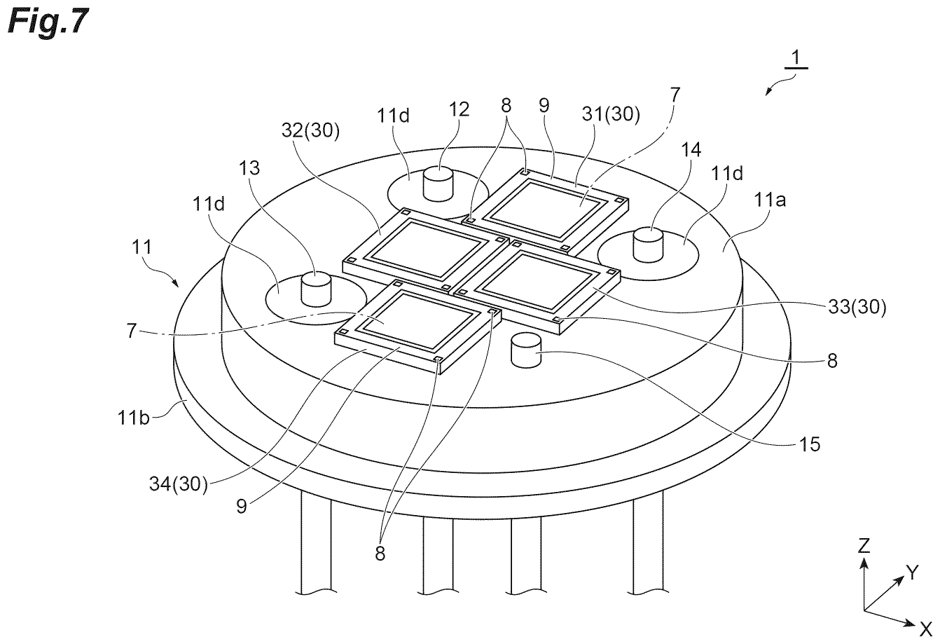

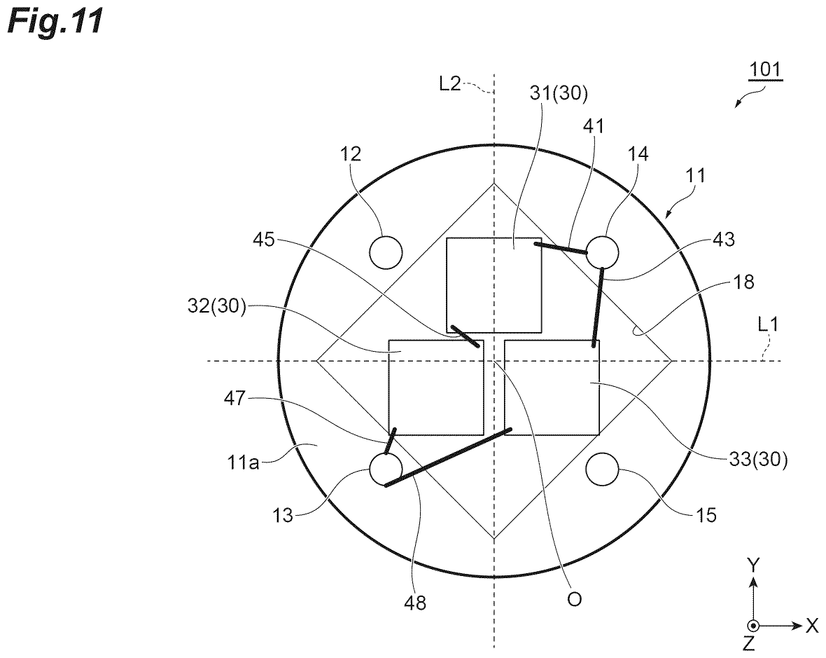

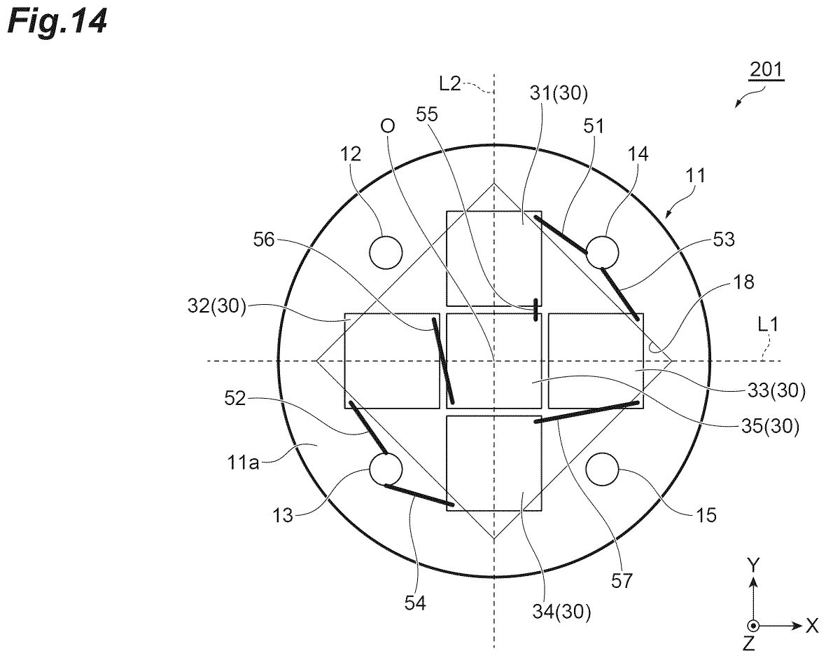

The first thermopile chip 31 is electrically connected to the third lead pin 14 by a first wire 41. The second thermopile chip 32 is electrically connected to the second lead pin 13 by a second wire 42. The third thermopile chip 33 is electrically connected to the third lead pin 14 by a third wire 43. The fourth thermopile chip 34 is electrically connected to the second lead pin 13 by a fourth wire 44. The first and second thermopile chips 31 and 32 are electrically connected to each other by a fifth wire 45. The third and fourth thermopile chips 33 and 34 are electrically connected to each other by a sixth wire 46. Although the electrode pad 8 (see FIG. 7) formed on the surface of the thermopile chip 30 is omitted in FIG. 8, each of the wires 41 to 46 is electrically connected to the electrode pad 8 (see FIG. 7) (the same applies to FIGS. 8, 11, 14, 17, and 19 below).

For wire bonding between the thermopile chip 30 and the second and third lead pins 13 and 14, for example, a second reinforcement method may be used. The second reinforcing method is a method of forming a reinforcing ball at a second bond point where strength is likely to be weaker than that at a first bond point after normal wire bonding is performed. Further, wire bonding between the plurality of thermopile chips 30 may be performed using a bond stick on ball (BSOB) method. The BSOB method is a method of forming a ball in advance at a point where second bonding is performed before the normal wire bonding is performed to reinforce the second bonding point.

As described above, in the infrared detector 1, the first chip unit U1 including the first and second thermopile chips 31 and 32 electrically connected in series and the second chip unit U2 including the third thermopile chip 33 are electrically connected in parallel, so that the resistance value (total resistance value) of a circuit can be reduced as compared with a case where the first to third thermopile chips 31 to 33 are electrically connected in series. In addition, arrangement of the first to third thermopile chips 31 to 33 can be optimized to ensure a large light receiving area while there is a restriction on arrangement of the thermopile chips 30 on the main surface 11a due to a package structure in which the first to fourth lead pins 12 to 15 protrude from the main surface 11a. The plurality of thermopile chips 30 can be effectively spread over a wide range on the main surface 11a. Therefore, sensitivity can be improved according to the infrared detector 1.

In the infrared detector 1, the light passing opening 18 is formed in the cap portion 16, and the light passing opening 18 overlaps the first to third thermopile chips 31 to 33 and does not overlap the first to third lead pins 12 to 14 as viewed from the Z direction. Thus, the infrared rays can be efficiently incident on the light receiving surfaces of the first to third thermopile chips 31 to 33 while preventing the infrared rays passing through the light passing opening 18 from hitting the first to third lead pins 12 to 14 and being irregularly reflected to generate noise.

In the infrared detector 1, the plurality of thermopile chips 30 further include a fourth thermopile chip 34. The third and fourth thermopile chips 33 and 34 are electrically connected in series. The first and fourth thermopile chips 31 and 34 are arranged side by side on the second straight line L2 via the reference position O as viewed from the Z direction. This makes it possible to optimize arrangement of the first to fourth thermopile chips 31 to 34 to ensure a large light receiving area, while suppressing the resistance value of the circuit to the same resistance value as in a case of using one thermopile chip 30.

In the infrared detector 1, the light passing opening 18 overlaps the first to fourth thermopile chips 31 to 34 and does not overlap the first to third lead pins 12 to 14 as viewed from the Z direction. Thus, the infrared rays can be efficiently incident on the light receiving surfaces of the first to fourth thermopile chips 31 to 34 while preventing the infrared rays passing through the light passing opening 18 from being irregularly reflected by the first to third lead pins 12 to 14 to generate noise.

In the infrared detector 1, the first to sixth wires 41 to 46 electrically connect the first and third thermopile chips 31 and 33 to the third lead pin 14, electrically connect the second and fourth thermopile chips 32 and 34 to the second lead pin 13, electrically connect the first and second thermopile chips 31 and 32 to each other, and electrically connect the third and fourth thermopile chips 33 and 34 to each other. In this case, as the arrangement of the first to fourth thermopile chips 31 to 34 can be optimized, lengths of the first to sixth wires 41 to 46 can be shortened to reduce the resistance value, and the sensitivity can be further improved.

In the infrared detector 1, the thermopile chip 30 and the light passing opening 18 both have a rectangular shape as viewed from the Z direction. The straight line along the diagonal line of the thermopile chip 30 is inclined by 45° with respect to the straight line along the diagonal line of the light passing opening 18. Thus, the infrared rays can be efficiently incident on the light receiving surfaces of the plurality of thermopile chips 30 while preventing the infrared rays from hitting the first to third lead pins 12 to 14 through the light passing opening 18. In addition, since the light passing opening 18 is inclined by 45° as described above, it is possible to easily realize the above-described arrangement configuration in which the light passing opening 18 overlaps the first to third thermopile chips 31 to 33 and does not overlap the first to third lead pins 12 to 14.

In the infrared detector 1, the thermopile chip 30 and the light passing opening 18 both have a square shape as viewed from the Z direction. The length of one side of the light passing opening 18 is larger than twice the length of one side of the thermopile chip 30. By increasing the light passing opening 18 in this manner, the infrared rays can be efficiently incident on the light receiving surface of the thermopile chip 30.

In the infrared detector 1, each of the thermopile chips 30 includes the membrane 7 formed in the central portion and the edge portion 9 surrounding the membrane 7 as viewed from the Z direction. The light passing opening 18 overlaps the membrane 7 of the thermopile chip 30 and does not overlap at least a part of the edge portion 9 as viewed from the Z direction. This makes it possible to easily realize a configuration in which the light passing opening 18 does not overlap the first to third lead pins 12 to 14 as viewed from the Z direction, while the infrared rays are efficiently incident on the membrane 7 on which the hot junction is formed. In FIG. 6, if the light passing opening 18 overlaps all portions of the plurality of thermopile chips 30, the light passing opening 18 also overlaps the first to third lead pins 12 to 14.

In the infrared detector 1, as viewed from the Z direction, the light passing opening 18 is disposed on the straight line connecting the first and second lead pins 12 and 13, and is disposed on the straight line connecting the first and third lead pins 12 and 14. Thus, the light passing opening 18 is disposed on the light receiving surfaces of the plurality of thermopile chips 30, and the infrared rays can be efficiently incident on the light receiving surfaces of the plurality of thermopile chips 30 through the light passing opening 18.

In the infrared detector 1, at least a part of the second thermopile chip 32 is located between the first thermopile chip 31 and the fourth thermopile chip 34 as viewed from the Z direction. At least a part of the third thermopile chip 33 is located between the first thermopile chip 31 and the fourth thermopile chip 34 as viewed from the Z direction. Thus, the second thermopile chip 32 and the third thermopile chip 33 can be brought close to each other in the X direction, and the infrared rays can be efficiently incident on the light receiving surfaces of the second and third thermopile chips 32 and 33.

In the infrared detector 1, the package 10 further includes the fourth lead pin 15, and when viewed from the Z direction, the second and fourth lead pins 13 and 15 are arranged side by side in the X direction via the second straight line L2, and the fourth thermopile chip 34 is disposed on the straight line connecting the second and fourth lead pins 13 and 15. Thus, the infrared rays can be efficiently incident on the light receiving surface of the fourth thermopile chip 34.

In the infrared detector 1, the light passing opening 18 overlaps the first to fourth thermopile chips 31 to 34 and does not overlap the first to fourth lead pins 12 to 15 as viewed from the Z direction. Thus, the infrared rays can be efficiently incident on the light receiving surfaces of the first to fourth thermopile chips 31 to 34 while preventing the infrared rays from hitting the first to fourth lead pins 12 to 15 through the light passing opening 18.

In the infrared detector 1, the reference position O overlaps the center position of the light passing opening 18 as viewed from the Z direction. Thus, the plurality of thermopile chips 30 can be arranged based on the center position of the light passing opening 18 as viewed from the Z direction, and the infrared rays passing through the light passing opening 18 can be efficiently incident on the light receiving surfaces of the plurality of thermopile chips 30.

Note that in the infrared detector 1, since the plurality of thermopile chips 30 are arranged as described above, the central portion of the light receiving surface of each of the plurality of thermopile chips 30 can be configured to be closer to the center position of the light passing opening 18 as compared with, for example, a case where the plurality of thermopile chips 30 are arranged in a lattice pattern. A center distance of the light receiving surface of each thermopile chip 30 can be reduced. Thus, since the central portion of the thermopile chip 30 has higher sensitivity than the edge portion 9, the infrared rays passing through the light passing opening 18 can be effectively incident on the light receiving surfaces of the plurality of thermopile chips 30. In addition, it is possible to increase a viewing angle of infrared rays incident on the plurality of thermopile chips 30 through the light passing opening 18. As a result, the sensitivity of the infrared detector 1 can be further improved.

In the infrared detector 1, as viewed from the Z direction, the light passing opening 18 is disposed on the straight line connecting the second and fourth lead pins 13 and 15, and is disposed on the straight line connecting the third and fourth lead pins 14 and 15. Further, as viewed from the Z direction, the light passing opening 18 is disposed on a straight line connecting the first and fourth lead pins 12 and 15, and is disposed on a straight line connecting the second and third lead pins 13 and 14. Even with such a configuration, since the light passing opening 18 is disposed on the light receiving surfaces of the plurality of thermopile chips 30, the infrared rays can be efficiently incident on the light receiving surfaces of the plurality of thermopile chips 30 through the light passing opening 18.

In the infrared detector 1, a general-purpose package in which the positions of the first to fourth lead pins 12 to 15 with respect to the main surface 11a of the base portion 11 are standardized is used as the package 10. Thus, members can be shared with the general-purpose package. As the general-purpose package, for example, TO-5 or the like can be used.

### Second Embodiment

Next, a second embodiment will be described. In the description of the present embodiment, points different from the first embodiment will be described, and the redundant description will be omitted.

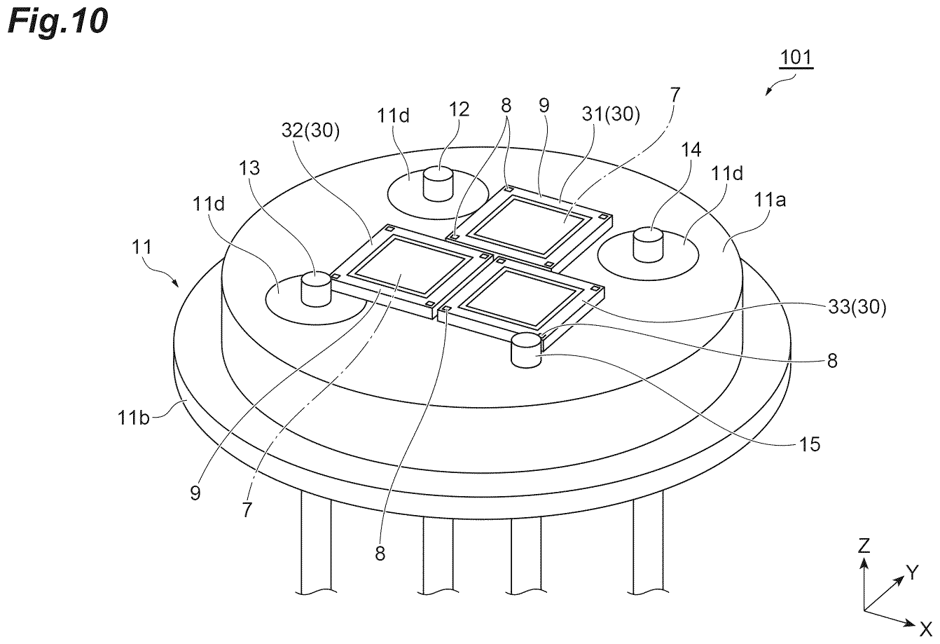

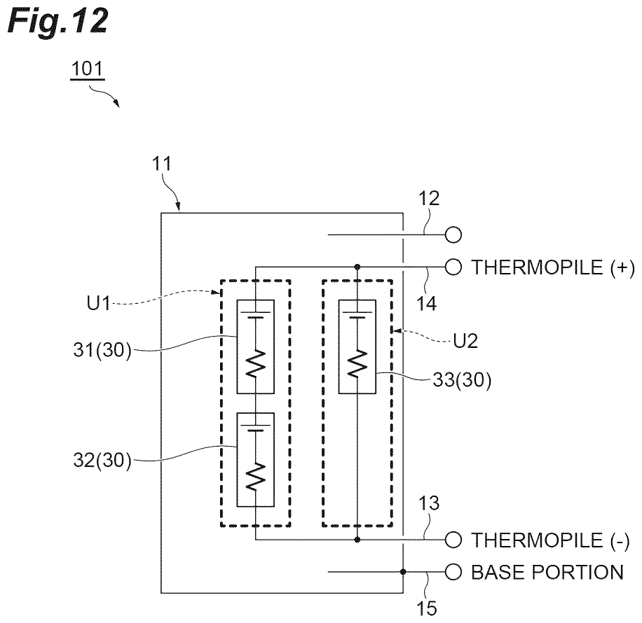

As illustrated in FIGS. 10, 11, and 12, an infrared detector 101 according to the second embodiment is different from the first embodiment in that the fourth thermopile chip 34 is not provided. The first chip unit U1 including the first and second thermopile chips 31 and 32 and the second chip unit U2 including the third thermopile chip 33 are electrically connected in parallel. The second thermopile chip 32 is electrically connected to the second lead pin 13 by a seventh wire 47. The third thermopile chip 33 is electrically connected to the second lead pin 13 by an eighth wire 48.

As described above, also in the infrared detector 101, effects similar to those of the first embodiment, that is, effects of enabling improvement in sensitivity and the like are exhibited.

### Third Embodiment

Next, a third embodiment will be described. In description of the present embodiment, points different from the first embodiment will be described, and the redundant description will be omitted.

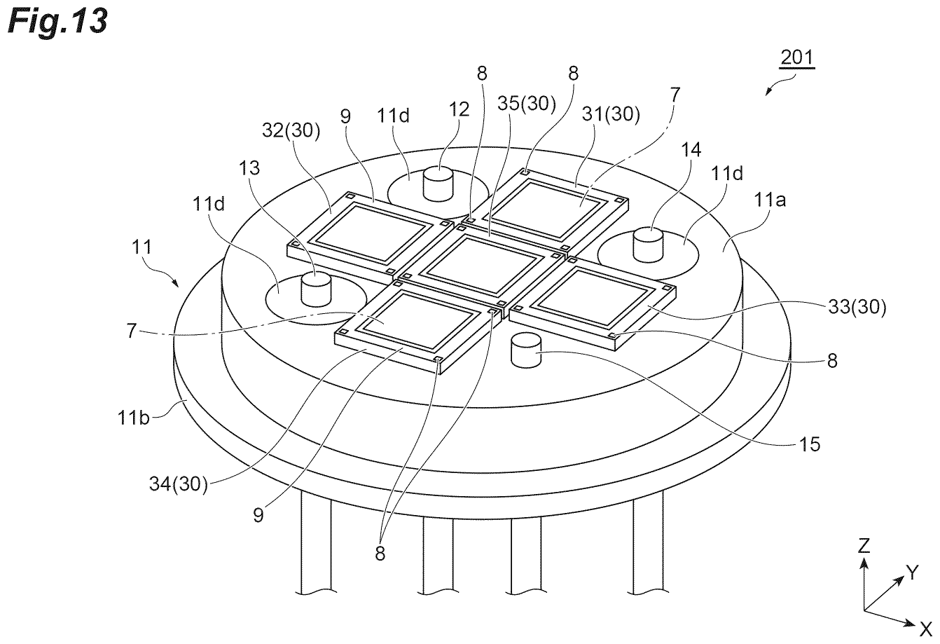

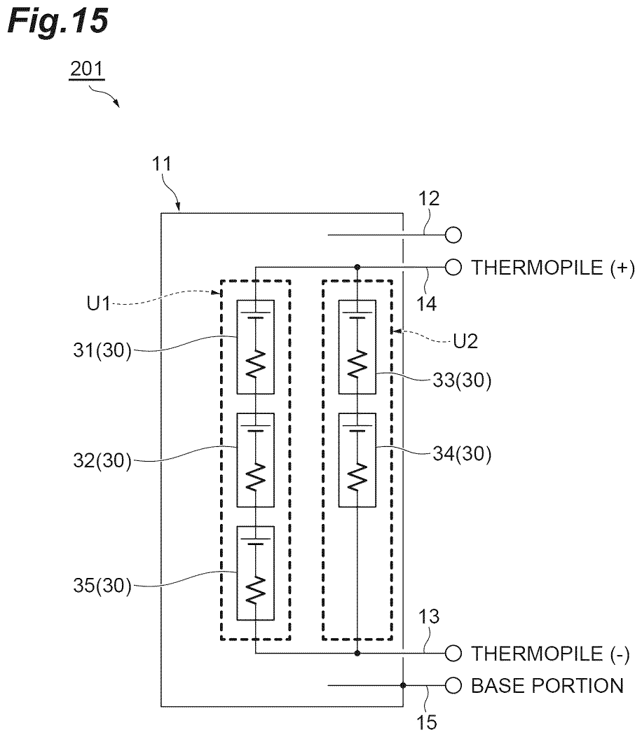

As illustrated in FIGS. 13, 14, and 15, an infrared detector 201 according to the third embodiment is different from the first embodiment in further including a fifth thermopile chip 35. The fifth thermopile chip 35 is disposed so as to overlap the reference position O as viewed from the Z direction. The fifth thermopile chip 35 is disposed between the second and third thermopile chips 32 and 33 as viewed from the Z direction. The fifth thermopile chip 35 is disposed between the first and fourth thermopile chips 31 and 34 as viewed from the Z direction. The fifth thermopile chip 35 is electrically connected in series with the first and second thermopile chips 31 and 32. The fifth thermopile chip 35 is included in the first chip unit U1.

The second thermopile chip 32 is disposed on the straight line connecting the first and second lead pins 12 and 13. The third thermopile chip 33 is disposed on the straight line connecting the third and fourth lead pins 14 and 15. The thermopile chips 30 are arranged to form a cross shape in the X direction and the Y direction as a whole. A maximum of three thermopile chips 30 are arranged in the X direction, and a maximum of three thermopile chips 30 are arranged in the Y direction. The light passing opening 18 overlaps the first to fifth thermopile chips 31 to 35 as viewed from the Z direction. The first chip unit U1 including the first, second, and fifth thermopile chips 31,32, and 35 and the second chip unit U2 including the third and fourth thermopile chips 33 and 34 are electrically connected in parallel.

The first thermopile chip 31 is electrically connected to the third lead pin 14 by a ninth wire 51. The second thermopile chip 32 is electrically connected to the second lead pin 13 by a 10th wire 52. The third thermopile chip 33 is electrically connected to the third lead pin 14 by a 11th wire 53. The fourth thermopile chip 34 is electrically connected to the second lead pin 13 by a 12th wire 54. The first and fifth thermopile chips 31 and 35 are electrically connected to each other by a 13th wire 55. The second and fifth thermopile chips 32 and 35 are electrically connected to each other by a 14th wire 56. The third and fourth thermopile chips 33 and 34 are electrically connected to each other by a 15th wire 57.

As described above, also in the infrared detector 201, the effects similar to those of the first embodiment, that is, the effects of enabling improvement in sensitivity and the like are exhibited. The infrared detector 201 further includes the fifth thermopile chip 35. This makes it possible to further improve the sensitivity due to the presence of the fifth thermopile chip 35. In the infrared detector 201, the fifth thermopile chip 35 is disposed so as to overlap the reference position O between the second and third thermopile chips 32 and 33 as viewed from the Z direction. Thus, arrangement of the first to fifth thermopile chips 31 to 35 can be optimized to ensure a large light receiving area.

In the infrared detector 201, the light passing opening 18 overlaps the first to fifth thermopile chips 31 to 35 and does not overlap the first to fourth lead pins 12 to 15. Thus, the infrared rays can be efficiently incident on the light receiving surfaces of the first to fifth thermopile chips 31 to 35 while preventing the infrared rays from hitting the first to fourth lead pins 12 to 15 through the light passing opening 18.

### [Modifications]

An aspect of the present disclosure is not limited to the above embodiments.

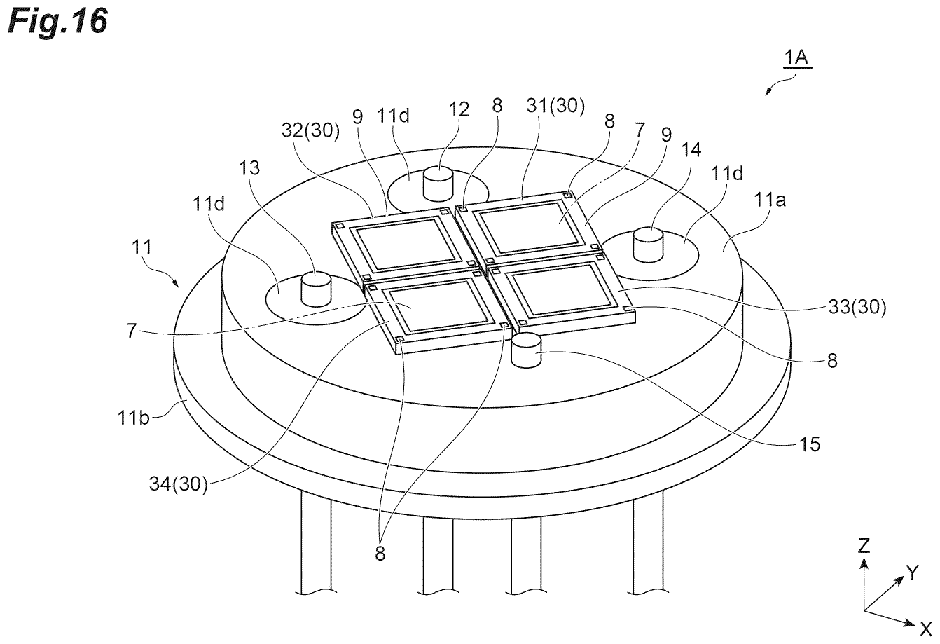

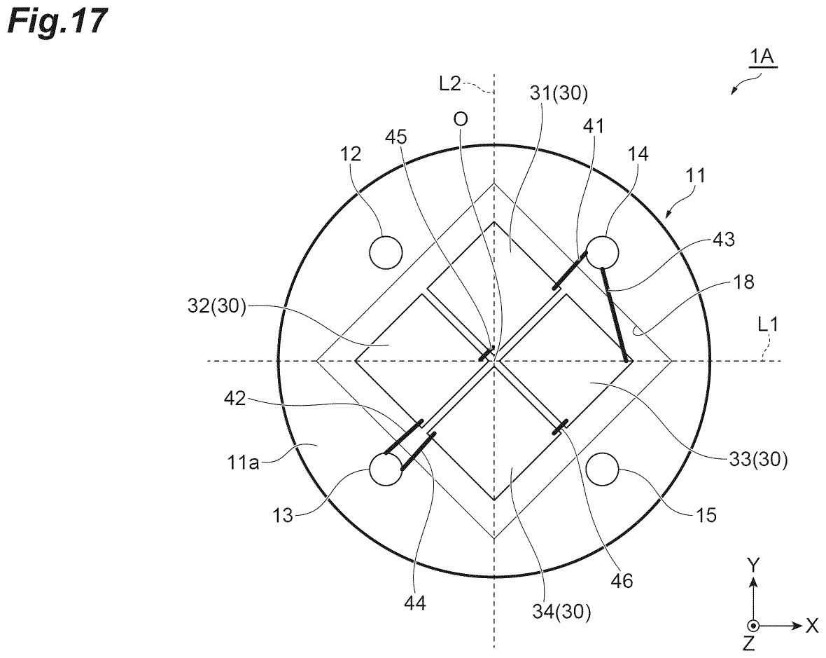

In the above embodiments, a direction of the thermopile chip 30 when viewed from the Z direction (an angle between each side of the thermopile chip 30 and the X direction or the Y direction) is not particularly limited. For example, as illustrated in FIGS. 16 and 17, in an infrared detector 1A according to a modification, the first to fourth thermopile chips 31 to 34 may be arranged to be rotated by 45° as viewed from the Z direction with respect to the direction of thermopile chip 30 of the infrared detector 1 (see FIG. 7). In this case, the first to fourth thermopile chips 31 to 34 are arranged such that an angle between each side and the X direction or the Y direction is 45°. The first to fourth thermopile chips 31 to 34 are arranged in a lattice pattern. The first to fourth thermopile chips 31 to 34 are arranged in a square shape as a whole. Even in this case, the same effects as those of the above embodiments are exhibited.

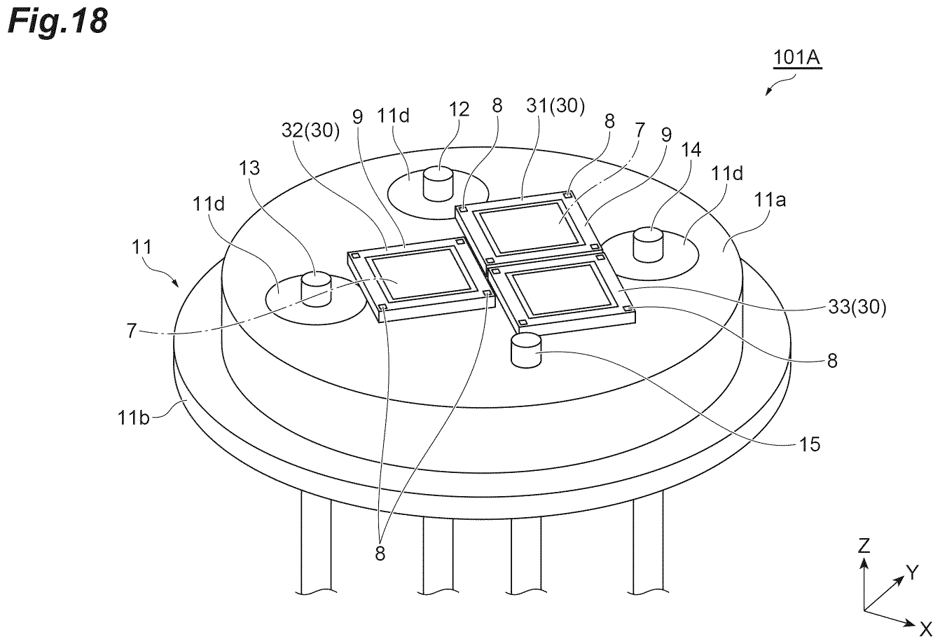

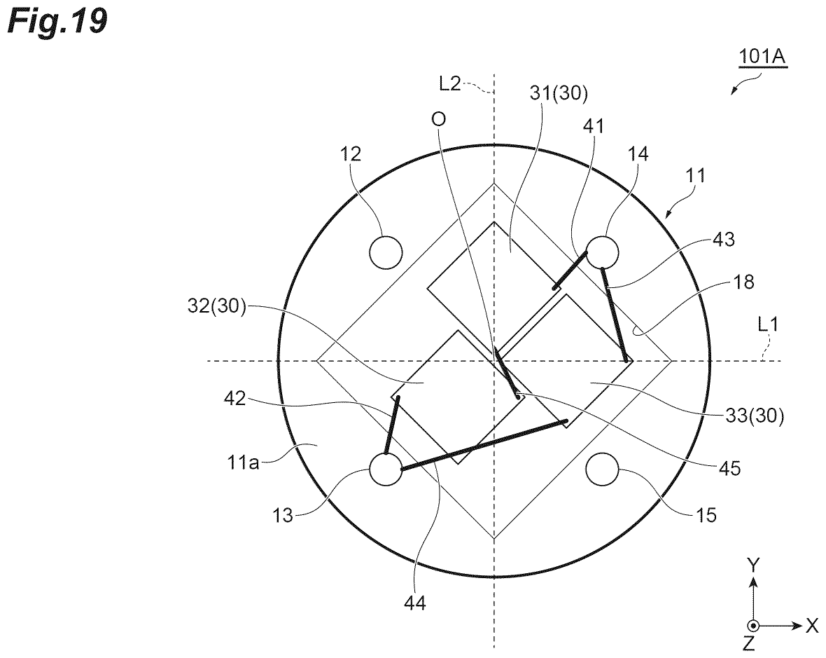

Further, for example, as illustrated in FIGS. 18 and 19, in an infrared detector 101A according to the modification, the first to third thermopile chips 31 to 33 may be arranged so as to be rotated by 45° as viewed from the Z direction with respect to the direction of the thermopile chip 30 of the infrared detector 101 (see FIG. 10). In this case, the first to third thermopile chips 31 to 33 are arranged such that the angle between each side and the X direction or the Y direction is 45°. Even in this case, the same effects as those of the above embodiments are exhibited.

In the above embodiments, the first to fifth thermopile chips 31 to 35 are rectangular chips having the same size, but the present invention is not limited thereto. Some or all of the first to fifth thermopile chips 31 to 35 may have different shapes or may have different sizes. In the above embodiments, the first lead pin 12 is not used, but the present invention is not limited thereto, and for example, the first lead pin 12 may be electrically connected to an output correction thermistor disposed on the main surface 11a.

In the above embodiments, the light passing opening 18 is formed so as not to overlap the first to fourth lead pins 12 to 15 as viewed from the Z direction, but the light passing opening 18 may be formed so as not to overlap the first to third lead pins 12 to 14. In this case, the infrared rays can be prevented from hitting the first to third lead pins 12 to 14. In the above embodiments, the reference position O is the center position of the main surface 11a of the base portion 11 and the center position of the light passing opening 18, but the present invention is not limited thereto. The reference position O may be an arbitrary position on the main surface 11a.

Each configuration in one embodiment or modification described above can be arbitrarily applied to each configuration in another embodiment or modification. In the above description, “45°” includes not only completely 45° but also approximately 45°, and can include errors due to manufacturing, design, or the like. In the above description, “twice” includes not only completely twice but also almost twice, and can include the errors due to manufacturing, design, or the like. In the above description, “arranged side by side in the first/second direction” is not limited to a case where a plurality of elements is arranged on a straight line extending in parallel with the first or second direction, and the plurality of elements may be shifted in a direction intersecting the first/second direction.

### REFERENCE SIGNS LIST

1, 1A, 101, 101A, 201 Infrared detector
7 Membrane
9 Edge portion
10 Package
11 Base portion
11a Main surface
12 First lead pin
13 Second lead pin
14 Third lead pin
15 Fourth lead pin
16 Cap portion
18 Light passing opening
30 Thermopile chip
31 First thermopile chip
32 Second thermopile chip
33 Third thermopile chip
34 Fourth thermopile chip
35 Fifth thermopile chip
41 First wire
42 Second wire
43 Third wire
44 Fourth wire
45 Fifth wire
46 Sixth wire
L1 First straight line
L2 Second straight line
O Reference position
R Housing space
U1 First chip unit
U2 Second chip unit.

1. An infrared detector comprising:
a package including a base portion, first to third lead pins protruding from a main surface of the base portion, and a cap portion disposed on the main surface of the base portion and defining a housing space together with the base portion; and
a plurality of thermopile chips arranged on the main surface of the base portion, wherein
the plurality of thermopile chips include first to third thermopile chips,
the first and second thermopile chips are electrically connected in series,
a first chip unit including the first and second thermopile chips and a second chip unit including the third thermopile chip are electrically connected in parallel,
in a case where as viewed from a direction perpendicular to the main surface of the base portion, a straight line passing through a reference position and extending in a first direction is a first straight line, and a straight line passing through the reference position and extending in a second direction orthogonal to the first direction is a second straight line,
the first and second lead pins are arranged side by side in the second direction via the first straight line,
the first and third lead pins are arranged side by side in the first direction via the second straight line,
the first thermopile chip is disposed on the second straight line and disposed on a straight line connecting the first and third lead pins, and
the second and third thermopile chips are arranged side by side on the first straight line via the reference position.

2. The infrared detector according to claim 1, wherein
a light passing opening facing the main surface of the base portion is formed in the cap portion, and
the light passing opening overlaps the first to third thermopile chips and does not overlap the first to third lead pins as viewed from the direction perpendicular to the main surface of the base portion.

3. The infrared detector according to claim 1, wherein
the plurality of thermopile chips further includes a fourth thermopile chip disposed on the main surface of the base portion and included in the second chip unit,
the third and fourth thermopile chips are electrically connected in series, and
the first and fourth thermopile chips are arranged side by side on the second straight line via the reference position as viewed from the direction perpendicular to the main surface of the base portion.

4. The infrared detector according to claim 3, wherein
a light passing opening facing the main surface of the base portion is formed in the cap portion, and
the light passing opening overlaps the first to fourth thermopile chips and does not overlap the first to third lead pins as viewed from the direction perpendicular to the main surface of the base portion.

5. The infrared detector according to claim 3, wherein
the first thermopile chip is electrically connected to the third lead pin by a first wire,
the second thermopile chip is electrically connected to the second lead pin by a second wire,
the third thermopile chip is electrically connected to the third lead pin by a third wire,
the fourth thermopile chip is electrically connected to the second lead pin by a fourth wire,
the first and second thermopile chips are electrically connected to each other by a fifth wire, and
the third and fourth thermopile chips are electrically connected to each other by a sixth wire.

6. The infrared detector according to claim 2, wherein the thermopile chip and the light passing opening both have a rectangular shape as viewed from the direction perpendicular to the main surface of the base portion, and a straight line along a diagonal line of the thermopile chip is inclined by 45° with respect to a straight line along a diagonal line of the light passing opening.

7. The infrared detector according to claim 2, wherein the thermopile chip and the light passing opening both have a square shape as viewed from the direction perpendicular to the main surface of the base portion, and a length of one side of the light passing opening is larger than twice a length of one side of the thermopile chip.

8. The infrared detector according to claim 2, wherein
each of the thermopile chips includes a membrane formed in a central portion as viewed from the direction perpendicular to the main surface of the base portion, and an edge portion surrounding the membrane, and
the light passing opening overlaps the membrane of the thermopile chip and does not overlap at least a part of the edge portion as viewed from the direction perpendicular to the main surface of the base portion.

9. The infrared detector according to claim 2, wherein the light passing opening is disposed on a straight line connecting the first and second lead pins and disposed on a straight line connecting the first and third lead pins as viewed from the direction perpendicular to the main surface of the base portion.

10. The infrared detector according to claim 3, wherein at least a part of the second thermopile chip is located between the first thermopile chip and the fourth thermopile chip, and at least a part of the third thermopile chip is located between the first thermopile chip and the fourth thermopile chip as viewed from the direction perpendicular to the main surface of the base portion.

11. The infrared detector according to claim 3, wherein
the package further includes a fourth lead pin protruding from the main surface of the base portion,
when viewed from the direction perpendicular to the main surface of the base portion,
the second and fourth lead pins are arranged side by side in the first direction via the second straight line, and
the fourth thermopile chip is disposed on a straight line connecting the second and fourth lead pins.

12. The infrared detector according to claim 11, wherein
a light passing opening facing the main surface of the base portion is formed in the cap portion, and
the light passing opening overlaps the first to fourth thermopile chips and does not overlap the first to fourth lead pins as viewed from the direction perpendicular to the main surface of the base portion.

13. The infrared detector according to claim 1, wherein
the plurality of thermopile chips further include a fifth thermopile chip disposed on the main surface of the base portion and included in the first chip unit, and
the first, second, and fifth thermopile chips are electrically connected in series.

14. The infrared detector according to claim 3, wherein
the plurality of thermopile chips further include a fifth thermopile chip disposed on the main surface of the base portion and included in the first chip unit,
the first, second, and fifth thermopile chips are electrically connected in series, and
the fifth thermopile chip is disposed so as to overlap the reference position between the second and third thermopile chips as viewed from the direction perpendicular to the main surface of the base portion.

15. The infrared detector according to claim 14, wherein
a light passing opening facing the main surface of the base portion is formed in the cap portion, and
the light passing opening overlaps the first to fifth thermopile chips and does not overlap the first to third lead pins as viewed from the direction perpendicular to the main surface of the base portion.

16. The infrared detector according to claim 2, wherein the reference position overlaps a center position of the light passing opening as viewed from the direction perpendicular to the main surface of the base portion.
